(19) United States
(12) Patent Application Publication
(10) Pub. No.: US 2011/0272731 A1
(43) Pub. Date: Nov. 10, 2011

(54) SUBSTRATE FOR LIGHT EMITTING ELEMENT PACKAGE, AND LIGHT EMITTING ELEMENT PACKAGE

(75) Inventors: Motohiro Suzuki, Tokyo (JP); Naomi Yonemura, Tokyo (JP); Tetsuro Maeda, Tokyo (JP); Eiji Yoshimura, Nagano (JP)

(73) Assignee: DENKI KAGAKU KOGYO KABUSHIKI KAISHA, Tokyo (JP)

(21) Appl. No.: 13/127,010

(22) PCT Filed: Oct. 31, 2008
(86) PCT No.: PCT/JP2008/069950

§ 371 Date: Jul. 26, 2011

(51) Int. Cl. H01L 33/62

(52) U.S. Cl. 257/99; 257/E33.062

(57) ABSTRACT

This invention provides a substrate for a light emitting element package that can obtain a sufficient heat dissipation effect from a light emitting element and can also lower the costs and reduce the size as a substrate for packaging the light emitting element, as well as a light emitting element package using the same. The substrate for a light emitting element package includes an insulating layer 1 composed of a resin 1a containing heat conductive fillers 1b, 1c, a thick metal section 2 formed under a mounting position of a light emitting element 4, and a surface electrode section 3 formed on a mounting side of said insulating layer 1 separately from said thick metal section 2.

### TECHNICAL FIELD

The present invention relates to a substrate for a light emitting element package used in packaging a light emitting element such as a LED chip, as well as to a light emitting element package using the same.

### BACKGROUND ART

In recent years, as illuminating and light-emitting means that can reduce the weight and thickness and can save electric power consumption, a light emitting diode has been attracting people's attention. As a mode of mounting a light emitting diode, there are known a method of mounting a bare chip (LED chip) of a light emitting diode directly on a circuit board and a method of packaging a LED chip by bonding on a small substrate so that the LED chip can be easily mounted on the circuit board and mounting this LED package on the circuit board.

A conventional LED package has a structure such that a LED chip is die-bonded onto a small substrate; the electrode part of the LED chip and the electrode part of the lead are connected with each other by wire bond or the like, and the resultant is sealed with a sealing resin having a light transmitting property.

On the other hand, a LED chip has a property such that, in an ordinary temperature region for use as an illumination appliance, the light-emitting efficiency increases according as the temperature goes down, and the light-emitting efficiency decreases according as the temperature goes up. For this reason, in a light source apparatus using a light emitting diode, quick dissipation of the heat generated in the LED chip to the outside so as to lower the temperature of the LED chip is an extremely important goal to be achieved in improving the light emitting efficiency of the LED chip. Also, by enhancing the heat dissipation characteristics, the LED chip can be energized with a large electric current, whereby the optical output of the LED chip can be increased.

Therefore, in order to improve the heat dissipation characteristics of a LED chip in place of a conventional light emitting diode, some light source apparatus are proposed in which the LED chip is directly die-bonded to a thermally conductive substrate. For example, in the following patent document 1, there is known an apparatus in which a recess is formed by performing a pressing treatment on a substrate made of a thin aluminum plate and, after a thin insulator film is formed on the surface thereof, a LED chip is die-bonded onto a bottom surface of the recess via the thin insulator film; the wiring pattern formed on the insulator film layer and the electrode on the LED chip surface are electrically connected via a bonding wire; and the inside of the recess is filled with a sealing resin having a light-transmitting property. However, with this substrate, the structure will be complex, raising problems such as a high processing cost.

Also, the following patent document 2 discloses an apparatus in which a substrate for mounting a light emitting element includes a metal substrate, a columnar metal body (metal protrusion) formed by etching at a mounting position of the metal substrate for mounting the light emitting element, an insulating layer formed around the columnar metal body, and an electrode section formed in a neighborhood of said columnar metal body.

Patent Document 1: Japanese Patent Application Laid-open No. 2002-94122 Gazette

Patent Document 2: Japanese Patent Application Laid-open No. 2005-167086 Gazette

### DISCLOSURE OF THE INVENTION

### Problems to be Solved by the Invention

However, according to the studies made by the present inventors, it has been found out that, in the case of mounting a LED chip on the circuit board, it will be important to dispose a columnar metal body at the mounting position thereof; however, in the case of mounting a LED package, there is not necessarily a need to dispose a columnar metal body on its substrate. In other words, it has been found out that, in the case of mounting a LED package, a sufficient heat dissipation property can be obtained by using a resin containing highly heat-conductive inorganic fillers as a material of the insulating layer of the substrate on which the LED package is to be mounted.

When reference is made to the patent document 2 from this viewpoint, with regard to the substrate for mounting a light emitting element disclosed in this document, there has further been a room for improvement as to the penetration structure of the columnar metal body, the wiring for electric power feeding, the insulating layer, and the like in packaging the LED chip.

Here, as a small substrate for packaging a LED chip, there is known one in which the insulating layer is made of ceramics; however, in producing the same, baking of the ceramics and the like will be needed, so that it has not been possible to say that it is advantageous in terms of production costs and the like.

Therefore, an object of the present invention is to provide a substrate for a light emitting element package that can obtain a sufficient heat dissipation effect from a light emitting element and can also lower the costs and reduce the size as a substrate for packaging the light emitting element, as well as a light emitting element package using the same.

### Means for Solving the Problems

The aforementioned object can be achieved by the present invention such as described below.

A substrate for a light emitting element package of the present invention is characterized by comprising:

an insulating layer composed of a resin containing heat conductive fillers and having a heat conductivity of 1.0 W/mK or more;

a thick metal section formed under a mounting position of a light emitting element; and

a surface electrode section formed on a mounting side of said insulating layer separately from said thick metal section.

According to the substrate for a light emitting element package of the present invention, the heat generated in the light emitting element is efficiently conducted by the thick metal section formed under the mounting position of the light emitting element, and the heat is efficiently conducted further through the insulating layer having a high heat conductivity, whereby a sufficient heat dissipation effect can be obtained as a substrate for packaging. Furthermore, the thick metal section is not required for penetrating through to the back surface, thereby simplifying the structure and facilitating the production. Therefore, the costs can be lowered and the size can be reduced.

In the present invention, it is preferable that a mounting surface of said thick metal section for mounting the light emitting element is exposed; said thick metal section is formed to be thick from the mounting surface towards a back surface of said insulating layer; and a bottom surface thereof penetrates through a part of or a whole of said insulating layer. With this structure, the mounting surface for mounting the light emitting element is exposed, so that the heat generated in the light emitting element is further more efficiently conducted. Moreover, the bottom side of the thick metal section is buried in the insulating layer having a high heat conductivity, thereby increasing the heat conduction area. Therefore, the heat from the thick metal section can be more efficiently conducted to the whole package.

It is preferable that it is further provided with an interlayer conduction section that establishes electrical conduction between said surface electrode section and the back surface of said insulating layer. Because the substrate has an interlayer conduction section that establishes electric conduction between the surface electrode section and the back surface of said insulating layer, electric power can be supplied to the light emitting element from the back surface of the substrate for the light emitting element package, whereby the package can be surface-mounted through a simple step by reflow soldering or the like.

On the other hand, a light emitting element package of the present invention comprises: the above substrate for a light emitting element package; a light emitting element mounted above said thick metal section; and a sealing resin for sealing the light emitting element. Therefore, the heat generated in the light emitting element is efficiently conducted by the thick metal section formed under the mounting position of the light emitting element, and the heat is efficiently conducted further through the insulating layer having a high heat conductivity, whereby a sufficient heat dissipation effect can be obtained as a light emitting element package. Furthermore, the thick metal section need not penetrate through to the back surface, thereby simplifying the structure and facilitating the production. Therefore, the costs can be lowered and the size can be reduced.

The preferred embodiment of a light emitting element package in the present invention comprises: the substrate for a light emitting element package, wherein a mounting surface of said thick metal section for mounting the light emitting element is exposed; said thick metal section is formed to be thick from the mounting surface towards a back surface of said insulating layer; and a bottom surface thereof penetrates through a part of or a whole of said insulating layer; a light emitting element mounted above said thick metal section; and a sealing resin for sealing the light emitting element. According to this light emitting element package, the mounting surface for mounting the light emitting element is exposed, so that the heat generated in the light emitting element is further more efficiently conducted. Moreover, the bottom side of the thick metal section is buried in the insulating layer having a high heat conductivity, thereby increasing the heat conduction area. Therefore, the heat from the thick metal section can be more efficiently conducted to the whole package.

### BRIEF DESCRIPTION OF THE DRAWINGS

FIG. 1 is a cross-sectional view showing one example of a substrate for a light emitting element package of the present invention.

FIG. 2 is a cross-sectional view showing another example of a substrate for a light emitting element package of the present invention.

FIG. 3 is a cross-sectional view showing another example of a substrate for a light emitting element package of the present invention.

FIG. 4 is a cross-sectional view showing another example of a substrate for a light emitting element package of the present invention.

FIG. 5 is a cross-sectional view showing another example of a substrate for a light emitting element package of the present invention.

FIG. 6 is a cross-sectional view showing another example of a substrate for a light emitting element package of the present invention.

FIG. 7 is a cross-sectional view showing another example of a light emitting element package of the present invention.

### DESCRIPTION OF THE SYMBOLS

1 insulating layer
2 thick metal section
3 surface electrode section
4 light emitting element
7 sealing resin
10 interlayer conduction section

### BEST MODES FOR CARRYING OUT THE INVENTION

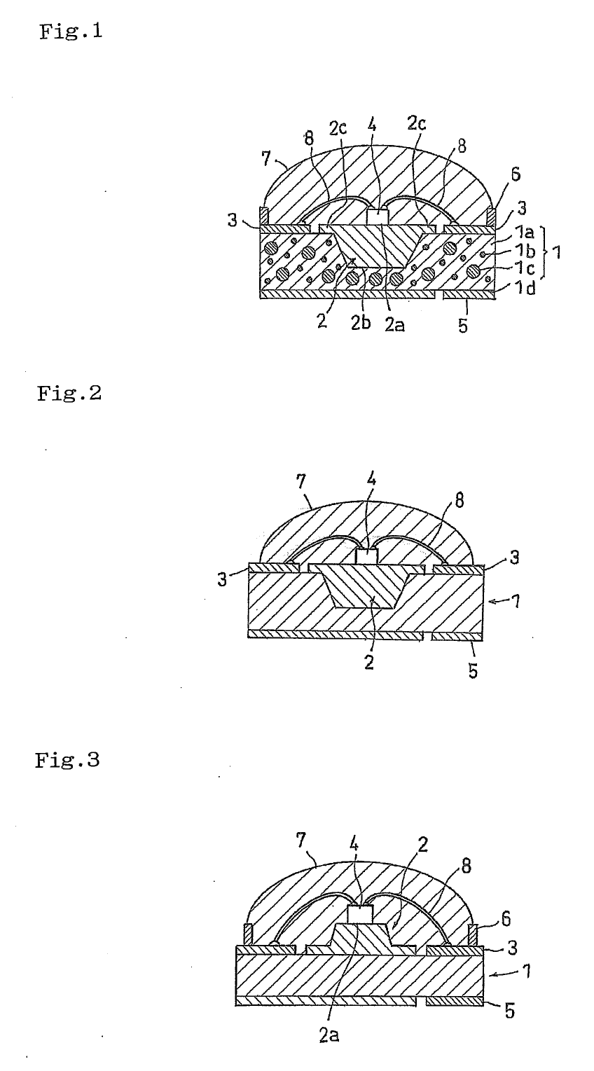

Hereafter, embodiments of the present invention will be described with reference to the drawings. FIG. 1 is a cross-sectional view showing one example of a substrate for a light emitting element package of the present invention, showing a state in which a light emitting element is mounted and packaged.

As shown in FIG. 1, the substrate for a light emitting element package of the present invention includes an insulating layer 1 composed of a resin 1a containing heat conductive fillers 1b, 1c; a thick metal section 2 formed under a mounting position of a light emitting element 4; and a surface electrode section 3 formed on a mounting side of the insulating layer 1 separately from the thick metal section 2.

In the present embodiment, an example is shown in which the mounting surface 2a of the thick metal section 2 for mounting the light emitting element 4 is exposed; the thick metal section 2 is formed to be thick from the mounting surface 2a towards the back surface of the insulating layer 1; and the bottom surface thereof penetrates through a part of the insulating layer 1. In this manner, in the case of a structure in which the bottom surface of the thick metal section 2 does not penetrate through the insulating layer 1, the structure can be produced only by thermal pressing as will be described later, thereby enabling cost reduction and downsizing.

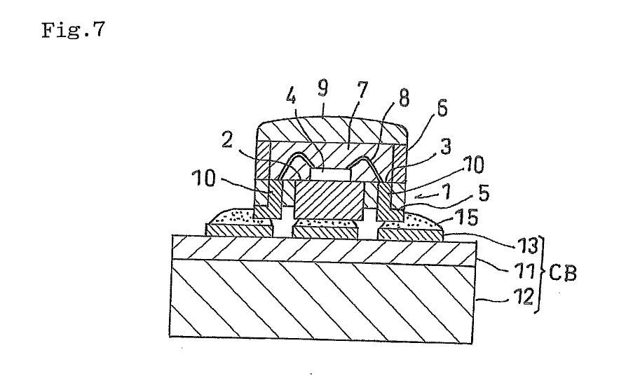

In this embodiment, the metal pattern 5 on the back surface of the insulating layer 1 is not electrically conducted to the surface electrode section 3. However, as shown in FIG. 7, it is preferably further provided with an interlayer conduction section 10 for establishing electrical conduction between the surface electrode section 3 and the back surface 1d of the insulating layer 1.

The insulating layer 1 in the present invention has a heat conductivity of 1.0 W/mK or more, preferably a heat conductivity of 1.2 W/mK or more, more preferably a heat conductivity of 1.5 W/mK or more. By this, the heat from the thick metal section 2 can be dissipated efficiently to the whole package. Here, the heat conductivity of the insulating layer 1 is determined by suitably selecting a blend in consideration of the amount of blending the heat conductive fillers and the particle size distribution. Typically, however, in consideration of the application property of the insulative adhesive agent before curing, the heat conductivity preferably has an upper limit of about 10 W/mK.

The insulating layer 1 is preferably composed of heat conductive fillers 1b, 1c, which are metal oxide and/or metal nitride, and a resin 1a. The metal oxide and metal nitride are preferably excellent in heat conductivity and electrically insulative. As the metal oxide, aluminum oxide, silicon oxide, beryllium oxide, and magnesium oxide can be selected. As the metal nitride, boron nitride, silicon nitride, and aluminum nitride can be selected. These can be used either alone or as a combination of two or more kinds. In particular, among the aforesaid metal oxides, aluminum oxide facilitates obtaining an insulating adhesive agent layer having both a good electric insulation property and a good heat conduction property, and also is available at a low price, so that it is preferable. Also, among the aforesaid metal nitrides, boron nitride is excellent in electric insulation property and heat conductivity, and further has a low electric permittivity, so that it is preferable.

As the heat conductive fillers 1b, 1c, those containing small-diameter fillers 1b and large-diameter fillers 1c are preferable. In this manner, by using two or more kinds of particles having different sizes (particles having different particle size distributions), the heat conductivity of the insulating layer 1 can be further improved by the heat conduction function provided by the large-diameter fillers 1c themselves and the function of enhancing the heat conductivity of the resin between the large-diameter fillers 1c that is provided by the small-diameter fillers 1b. From such a viewpoint, the average particle size of the small-diameter fillers 1b is preferably 3 to 20 μm, more preferably 4 to 10 μm. Also, the average particle size of the large-diameter fillers 1c is preferably 20 to 200 μm, more preferably 30 to 80 μm.

Also, even with a structure in which the bottom surface of the thick metal section 2 does not penetrate through the insulating layer 1 as in the present embodiment, the large-diameter fillers 1c intervene between the bottom surface 2b of the thick metal section 2 and the metal pattern 5, whereby the large-diameter fillers 1c are more easily brought into contact with the bottom surface 2b and the metal pattern 5 at the time of thermal pressing. As a result of this, a path of heat conduction is formed between the bottom surface 2b of the thick metal section 2 and the metal pattern 5, thereby further improving the heat dissipation property from the thick metal section 2 to the metal pattern 5.

As the resin la constituting the insulating layer 1, those having an excellent bonding force to the surface electrode section 3 and the metal pattern 5 under a cured state and not deteriorating the breakdown voltage characteristics and the like though containing the aforesaid metal oxide and/or metal nitride are selected.

As such a resin, in addition to epoxy resin, phenolic resin, and polyimide resin, various engineering plastics can be used either alone or by mixing two or more kinds. Among these, epoxy resin is preferable because of having an excellent bonding force between metals. In particular, among the epoxy resins, a bisphenol-A type epoxy resin and a bisphenol-F type epoxy resin having a high fluidity and being excellent in the mixing property with the aforesaid metal oxide and metal nitride are further more preferable resins.

For the thick metal section 2, the surface electrode section 3, and the metal pattern 5 in the present invention, various metals can be used. Typically, however, any one of copper, aluminum, nickel, iron, tin, silver, and titanium or an alloy or the like containing these metals can be used. In particular, from the viewpoint of heat conduction property and electrical conduction property, copper is preferable.

The thick metal section 2 means that the thickness thereof is larger than the thickness of the surface electrode section 3. In other words, it is sufficient that the thick metal section 2 of the present invention has a portion having a larger thickness than the surface electrode section 3, and may have a thin section 2c that is integrated with the thick metal section 2. The thickness of the thick metal section 2 (thickness from the bottom surface 2b to the mounting surface 2a) is preferably 31 to 275 μm, more preferably 35 to 275 μm, in view of sufficiently conducting the heat from the light emitting element 4 to the insulating layer 1. Also, from similar reasons, the portion of the thick metal section 2 that penetrates to the insulating layer 1 preferably has a thickness of 30 to 100%, more preferably 50 to 100% of the thickness of the insulating layer 1.

Also, in view of sufficiently conducting the heat from the light emitting element 4 to the insulating layer 1, the shape of the thick metal section 2 as viewed in a plan view is suitably selected; however, the shape is further preferably a polygonal shape such as a triangle or a quadrangle, a star-like polygonal shape such as a pentagram or a hexagram, or one in which the corners of any of these are rounded with a suitable circular arc, or further can be a shape that gradually changes from the 2a surface of the thick metal section towards the surface electrode section 3. Also, from similar reasons, the maximum width of the thick metal section 2 as viewed in a plan view is preferably 1 to 10 mm, more preferably 1 to 5 mm.

The thick metal section 2 may be formed of two or more kinds of metal layers and, for example, may be one in which a protective metal layer at the time of forming the thick metal section 2 by etching intervenes. As the protective metal layer, for example, gold, silver, zinc, palladium, ruthenium, nickel, rhodium, a lead-tin series solder alloy, a nickel-gold alloy, or the like can be used.

The thickness of the surface electrode section 3 is preferably about 25 to 70 μm, for example. Also, in the case of providing a metal pattern 5, the thickness of the metal pattern 5 is preferably about 25 to 70 μm. Here, the metal pattern 5 may cover the whole of the back surface of the insulating layer 1; however, in view of evading a short circuit of the surface electrode section 3, it is preferable that at least the metal patterns 5 of the back surfaces of the surface electrode sections 3 on both sides are not electrically conducted.

In view of enhancing the reflection efficiency, it is preferable to perform plating with a noble metal such as silver, gold, or nickel on the thick metal section 2 and the surface electrode section 3. Also, in the same manner as a conventional substrate, a solder resist may be formed, or partial solder plating may be performed.

Next, a suitable method for producing a substrate for a light emitting element package of the present invention such as described above will be described. First, with use of a metal plate or a metal laminate plate having the same thickness as the thick metal section 2, a metal plate whose etching-resist-forming part is made thick is fabricated by etching using the photolithography method or the like.

With use of a metal plate for forming the metal pattern 5 and an insulating-layer-forming material for forming the insulating layer 1 separately or one in which these are integrated, they are integrated with the metal plate having the thick metal section 2 by thermal pressing. By this, a two-sided metal laminate plate having metal plates on both sides can be formed in which the thick metal section 2 penetrates partially into the inside. In order to form a two-sided metal laminate plate in which the thick metal section 2 penetrates through the whole of the insulating layer 1, it is preferable to use a method disclosed in Japanese Patent No. 3907062 Gazette.

With use of this two-sided metal laminate plate, the two sides are patterned by etching using the photolithography method, so as to form the thick metal section 2, the surface electrode section 3, and the metal pattern 5. This is cut into a predetermined size by using a cutting apparatus such as a dicer, a router, a line cutter, or a slitter, whereby the substrate for a light emitting element package of the present invention can be obtained.

At this time, the substrate for a light emitting element package of the present invention may be of a type in which a single light emitting element is mounted as shown in FIG. 1 or of a type in which a plurality of light emitting elements are mounted. In particular, in the latter case, the substrate preferably has a wiring pattern that wires between the surface electrode sections 3.

The substrate for a light emitting element package of the present invention is used, for example, by mounting a light emitting element 4 above the thick metal section 2 of the substrate for a light emitting element package and sealing the light emitting element 4 with a sealing resin 7 as shown in FIG. 1.

In other words, the light emitting element package of the present invention includes a substrate for a light emitting element package including an insulating layer 1 composed of a resin la containing heat conductive fillers 1b, 1c, a thick metal section 2 formed under a mounting position of a light emitting element 4, and a surface electrode section 3 formed on a mounting side of the insulating layer 1 separately from the thick metal section 2; a light emitting element 4 mounted above the thick metal section 2; and a sealing resin 7 for sealing the light emitting element 4.

A suitable light emitting element package of the present invention is such that the mounting surface 2a of the thick metal section 2 for mounting the light emitting element 4 is exposed; the thick metal section 2 is formed to be thick from the mounting surface 2a towards the back surface of the insulating layer 1; and the bottom surface thereof penetrates through a part of or a whole of the insulating layer 1.

As the light emitting element 4 to be mounted, a LED chip, a semiconductor laser chip, and the like can be exemplified. Besides a face-up type in which both electrodes are present on an upper surface, the LED chip may be of a cathode type, an anode type, a face-down type (flip chip type), or the like depending on the back surface electrode. In the present invention, it is preferable to use a face-up type in view of the heat dissipation property.

The method of mounting the light emitting element 4 on the mounting surface of the thick metal section 2 may be any bonding method such as bonding with use of an electrically conductive paste, a two-sided tape, or a solder, or a method using a heat dissipating sheet (preferably a silicone series heat dissipating sheet), a silicone series or epoxy series resin material; however, bonding by metal is preferable in view of heat dissipation.

In the present embodiment, the light emitting element 4 is electrically conducted and connected to the surface electrode sections 3 on both sides. This electrical conduction and connection can be implemented by wiring between the upper electrode of the light emitting element 4 and each of the surface electrode sections 3 by wire bonding or the like using fine metal lines 8. For wire bonding, supersonic wave, a combination of this with heating, or the like can be used.

With regard to the light emitting element package of the present embodiment, an example is shown in which a dam section 6 at the time of potting a sealing resin 7 is disposed; however, the dam section 6 can be omitted, as shown in FIG. 2. As a method of forming the dam section 6, a method of bonding an annular member, a method of applying and curing an ultraviolet-curing resin or the like in a three-dimensional manner and in an annular manner with a dispenser, or the like method can be used.

As a resin used for potting, a silicone series resin, an epoxy series resin, and the like can be suitably used. For potting of the sealing resin 7, the upper surface thereof is preferably formed in a convex shape in view of imparting a function of a convex lens; however, the upper surface may be formed in a planar shape or in a concave shape. The upper surface shape of the potted sealing resin 7 can be controlled by the viscosity, the application method, the affinity to the applied surface, and the like of the material to be used.

In the present invention, a transparent resin lens having a convex shape may be provided above the sealing resin 7. When the transparent resin lens has a convex shape, light can be efficiently emitted upwards from the substrate in some cases. As the lens having a convex shape, those having a circular or elliptic shape as viewed in a plan view and the like can be raised as examples. Here, the transparent resin or the transparent resin lens may be a colored one or may be one containing a fluorescent substance. In particular, in the case of containing a yellow series fluorescent substance, white light can be generated by using a blue light emitting diode.

### Other Embodiments

(1) In the above-described embodiments, an example has been shown in which a light emitting element of a face-up type is mounted. However, in the present embodiment, a light emitting element of a face-down type provided with a pair of electrodes on the bottom surface may be mounted. In that case, there are cases in which there will be no need of wire bonding or the like by performing solder bonding or the like. Also, in the event that the front surface and the back surface of the light emitting element has an electrode, the wire bonding or the like can be formed with use of a single line.

(2) In the above-described embodiment, an example has been shown in which the thick metal section 2 is formed in a convex shape on the insulating layer 1 side (lower side), and the mounting surface 2a thereof is a flat surface. However, in the present invention, the thick metal section 2 may be formed in a convex shape on the mounting surface 2a side (upper side), as shown in FIG. 3. In this case as well, the heat from the light emitting element 4 can be efficiently conducted to the whole of the thick metal section 2, and is further conducted to the insulating layer 1, whereby a substrate for a light emitting element package is obtained in which a sufficient heat dissipation effect from the light emitting element 4 can be obtained, and also cost reduction and downsizing can be achieved.

In the case of fabricating a substrate having this structure, a two-sided metal laminate plate may be fabricated by turning the metal plate in which the thick metal section 2 has been formed in an opposite direction (upwards) to the above-described embodiment. At the time of patterning, the etching resist is preferably left so as to protect the thick metal section 2.

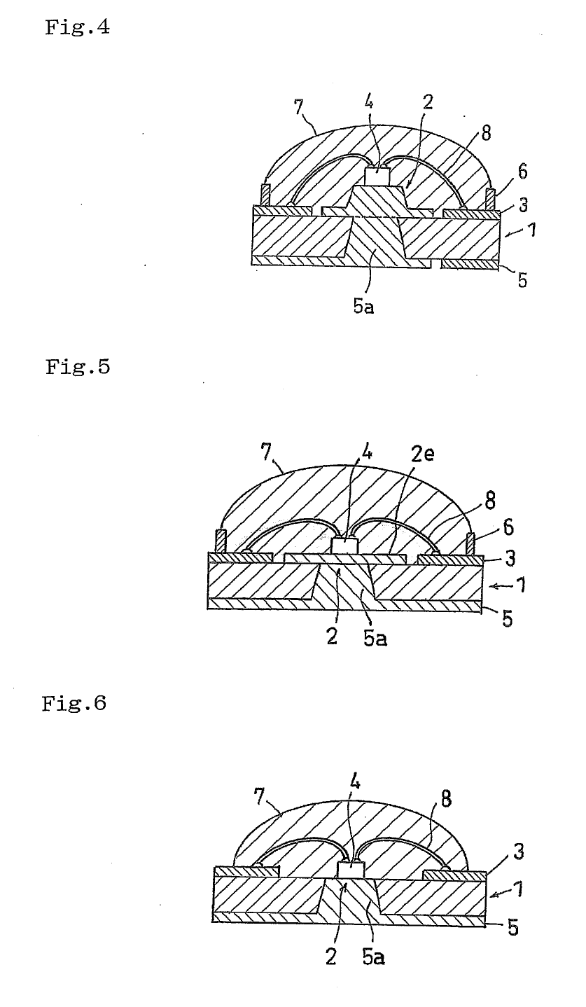

(3) In the above-described embodiment, an example has been shown in which the thick metal section 2 is formed in one stage. However, in the present invention, the thick metal section 2 may be formed in plural stages as shown in FIG. 4. In other words, the thick metal section 2 may be formed in a convex shape on the mounting surface 2a side (upper side), and also a convex section 5a may be formed in the metal pattern 5, whereby the thick metal section 2 may be formed in a state in which the two are in contact in an up-and-down direction. In this case, the heat from the light emitting element 4 can be more efficiently conducted to the whole substrate via the thick metal section 2. Here, in the case of forming the thick metal section 2 in plural stages, they may not be in contact with each other; however, they are preferably in contact with each other. In particular, from the viewpoint of heat conduction, the two are preferably bonded by plating.

In the case of fabricating a substrate having this structure, a two-sided metal laminate plate may be fabricated by using two sheets of metal plates in which a convex portion is formed and thermally pressing so that the convex sections of the two will be on the upper side.

(4) In the embodiment shown in FIG. 4, an example has been shown in which the thick metal section 2 is formed in plural stages by forming the convex section 5a also in the metal pattern 5. However, in the present invention, the convex section 5a may be formed in the metal pattern 5, and the thick metal section 2 may be formed in a state of being in contact with a mounting pad 2e, as shown in FIG. 5. In that case, the mounting pad 2e and the convex section 5a are preferably in contact and, from the viewpoint of heat conduction, the two are preferably bonded by plating.

Also, as shown in FIG. 6, the mounting pad 2e may be omitted, and the light emitting element 4 may be bonded to the metal pattern 5 directly onto the upper surface of the convex section 5a.

(5) In the above-described embodiment, an example has been shown having a structure such that the surface electrode section 3 is not electrically conducted to the back surface of the insulating layer 1. However, in the present invention, it is preferable that an interlayer conduction section 10 for establishing electrical conduction between the surface electrode section 3 and the back surface of the insulating layer 1 is further provided, as shown in FIG. 7. The interlayer conduction section 10 may be any of a through hole plating, an electrically conductive paste, a metal bump, and the like.

In the present invention, a substrate for a light emitting element package such as shown in FIG. 7 can be fabricated in a simple manner by forming an interlayer conduction section 10 and a thick metal section 2 as metal bumps on a metal plate, bonding and integrating an insulating-layer-forming material and the metal plate by thermal pressing, exposing the upper surface of the metal bumps and then patterning. As a method for exposing the upper surface of the metal bumps, polishing, exposure and development, chemical treatment, and the like can be raised as examples.

In this example, the lens 9 having a convex surface is bonded to the upper surface of the sealing resin 7, and a dam 6 is formed. However, the lens 9 and the dam 6 can be omitted. Also, a pad may be disposed on an upper surface of the metal bumps.

Here, as shown in FIG. 7, the light emitting element package of the present invention is, for example, solder-bonded to a circuit board CB for mounting. As the circuit board CB for mounting, one having a metal plate 12 for heat dissipation, an insulating layer 11, and a wiring pattern 13 is used, for example. By solder-bonding, the back surface side electrode (metal pattern 5) of the light emitting element package and the wiring pattern 13 are bonded via a solder 15. Also, the thick metal section 2 and the wiring pattern 13 are bonded via the solder 15.

(6) In the above-described embodiment, an example has been shown in the case where the light emitting element is mounted on a substrate in which the wiring layer is a single layer. However, in the present invention, the light emitting element may be mounted on a multi-layer wiring substrate in which the wiring layers are provided as plural layers. Details of the method for forming the electrically conductive connection structure in that case are disclosed in International Patent Publication WO00/52977, and any of these can be applied.

1. A substrate for a light emitting element package comprising:
an insulating layer composed of a resin containing heat conductive fillers and having a heat conductivity of 1.0 W/mK or more;
a thick metal section formed under a mounting position of a light emitting element;
a surface electrode section formed on a mounting side of said insulating layer separately from said thick metal section; and
a metal pattern formed on a back surface of said insulating layer,
wherein a mounting surface of said thick metal section for mounting the light emitting element is exposed; said thick metal section is formed to be thick from the mounting surface towards the back surface of said insulating layer; a bottom surface thereof penetrates through a part of said insulating layer; and said insulating layer intervenes between the bottom surface of said thick metal section and said metal pattern.

2. (canceled)

3. The substrate for a light emitting element package according to claim 1, further provided with an interlayer conduction section that establishes electrical conduction between said surface electrode section and the back surface of said insulating layer.

4. (canceled)

5. A light emitting element package comprising:
a substrate for a light emitting element package comprising an insulating layer composed of a resin containing heat conductive fillers and having a heat conductivity of 1.0 W/mK or more, a thick metal section formed under a mounting position of a light emitting element, a surface electrode section formed on a mounting side of said insulating layer separately from said thick metal section, and a metal pattern formed on a back surface of said insulating layer, wherein a mounting surface of said thick metal section for mounting the light emitting element is exposed; said thick metal section is formed to be thick from the mounting surface towards the back surface of said insulating layer; a bottom surface thereof penetrates through a part of said insulating layer; and said insulating layer intervenes between the bottom surface of said thick metal section and said metal pattern;
a light emitting element mounted above said thick metal section; and
a sealing resin for sealing the light emitting element.

6. (canceled)

7. The light emitting element package according to claim 5, further provided with an interlayer conduction section that establishes electrical conduction between said surface electrode section and the back surface of said insulating layer.

8. (canceled)
